(19) United States
(12) Patent Application Publication
(10) Pub. No.: US 2026/0040448 A1
(43) Pub. Date: Feb. 5, 2026

(54) WIRING SUBSTRATE

(71) Applicant: IBIDEN CO., LTD., Gifu (JP)

(72) Inventors: Kyohei YOSHIKAWA, Ogaki (JP); Yuma ITO, Ogaki (JP)

(73) Assignee: IBIDEN CO., LTD., Gifu (JP)

(21) Appl. No.: 19/285,304

(22) Filed: Jul. 30, 2025

(30) Foreign Application Priority Data
Aug. 2, 2024 (JP) 2024-127857

(51) Int. Cl. H05K 1/11

(52) U.S. Cl. CPC H05K 1/115; H05K 2201/09563; H05K 2201/096; H05K 2201/09909; H05K 2201/09981

(57) ABSTRACT

A wiring substrate includes a first conductor layer, an insulating layer covering the first conductor layer, a second conductor layer formed on a surface of the insulating layer, and a via conductor formed in a hole penetrating through the insulating layer such that the via conductor is connecting the first conductor layer and the second conductor layer. The insulating layer is formed such that the hole includes a first portion decreasing in width on the first conductor layer side, a second portion formed on the first conductor layer side of the first portion and increasing in width on the first conductor layer side, and a third portion formed on the first conductor layer side of the second portion and decreasing in width on the first conductor layer side.

### CROSS-REFERENCE TO RELATED APPLICATIONS

The present application is based upon and claims the benefit of priority to Japanese Patent Application No. 2024-127857, filed Aug. 2, 2024, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2020-17639 describes a wiring substrate. The entire contents of this publication are incorporated herein by reference.

### SUMMARY OF THE INVENTION

According to one aspect of the present invention, a wiring substrate includes a first conductor layer, an insulating layer covering the first conductor layer, a second conductor layer formed on a surface of the insulating layer, and a via conductor formed in a hole penetrating through the insulating layer such that the via conductor is connecting the first conductor layer and the second conductor layer. The insulating layer is formed such that the hole includes a first portion decreasing in width on the first conductor layer side, a second portion formed on the first conductor layer side of the first portion and increasing in width on the first conductor layer side, and a third portion formed on the first conductor layer side of the second portion and decreasing in width on the first conductor layer side.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is an enlarged view of a portion (II) of the wiring substrate of FIG. 1;

FIG. 3 is a photographed image of a cross section of a via conductor in a wiring substrate according to an embodiment of the present invention;

FIG. 4 is a cross-sectional view illustrating a first modified example of a wiring substrate according to an embodiment of the present invention;

FIG. 5 is a cross-sectional view illustrating a second modified example of a wiring substrate according to an embodiment of the present invention;

FIG. 6A is a cross-sectional view illustrating an example of a wiring substrate according to an embodiment of the present invention during a manufacturing process;

FIG. 6B is a cross-sectional view illustrating an example of a wiring substrate according to an embodiment of the present invention during a manufacturing process;

FIG. 6C is a cross-sectional view illustrating an example of a wiring substrate according to an embodiment of the present invention during a manufacturing process;

FIG. 6D is a cross-sectional view illustrating an example of a wiring substrate according to an embodiment of the present invention during a manufacturing process;

FIG. 6E is a cross-sectional view illustrating an example of a wiring substrate according to an embodiment of the present invention during a manufacturing process;

FIG. 6F is a cross-sectional view illustrating an example of a wiring substrate according to an embodiment of the present invention during a manufacturing process;

FIG. 6G is a cross-sectional view illustrating an example of a wiring substrate according to an embodiment of the present invention during a manufacturing process; and

FIG. 6H is a cross-sectional view illustrating an example of a wiring substrate according to an embodiment of the present invention during a manufacturing process.

### DETAILED DESCRIPTION OF THE EMBODIMENTS

Embodiments will now be described with reference to the accompanying drawings, wherein like reference numerals designate corresponding or identical elements throughout the various drawings.

### Basic Structure of a Wiring Substrate

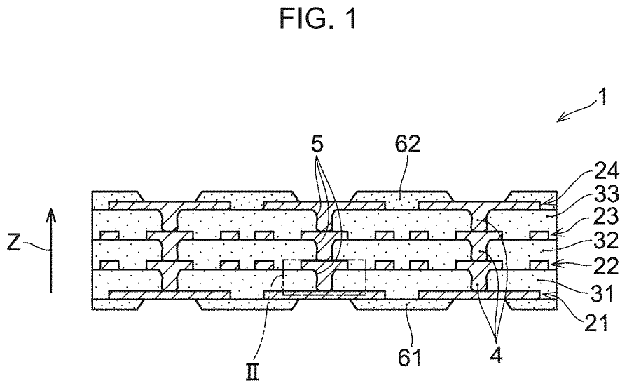

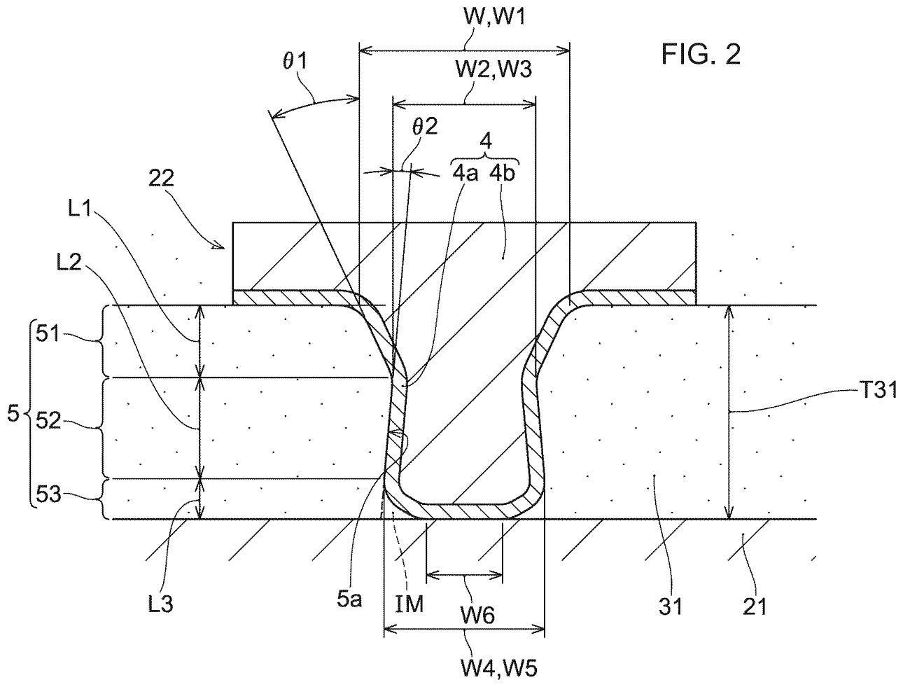

A wiring substrate of an embodiment of the present invention is described with reference to the drawings. FIG. 1 illustrates a wiring substrate 1, which is an example of the wiring substrate of the embodiment. FIG. 2 illustrates an enlarged view of a portion (II) of the wiring substrate 1 of FIG. 1. The wiring substrate illustrated in the drawings referenced in the following description is merely an example of the wiring substrate of the embodiment. A laminated structure of the wiring substrate of the embodiment is not limited to the laminated structure of the wiring substrate illustrated in the drawings, and the number of conductor layers and the number of insulating layers included in the wiring substrate of the embodiment are not limited to the number of conductor layers and the number of insulating layers included in the wiring substrate illustrated in the drawings. The wiring substrate of the embodiment may include, in addition to the insulating layers and conductor layers included in the wiring substrate illustrated in the drawings, any number of insulating layers and conductor layers, and it is also possible that all of the insulating layers and conductor layers included in the wiring substrate illustrated in the drawings are not included. In the drawings to be referenced in the following description, in order to facilitate understanding of the embodiment to be disclosed, a specific portion may be depicted in an enlarged manner. Therefore, it may be possible that structural elements are not depicted in precise proportions in terms of size or length relative to each other.

As illustrated in FIG. 1, the wiring substrate 1 includes conductor layers (21-24) and insulating layers (31-33). The conductor layers (21-24) and the insulating layers (31-33) are alternately laminated. A lamination direction of these conductor layers and insulating layers is a thickness direction of the wiring substrate 1, and is hereinafter also referred to as a “Z direction”. In FIG. 1, the insulating layer 31 is laminated to cover one of two surfaces of the conductor layer 21 orthogonal to the Z direction, and on a side of the insulating layer 31 opposite to the conductor layer 21, the conductor layer 22, the insulating layer 32, the conductor layer 23, the insulating layer 33, and the conductor layer 24 are laminated in this order.

In the following description of the wiring substrate of the embodiment, in the wiring substrate 1, the conductor layer 24 side is also referred to as an “upper side,” and the conductor layer 21 side is also referred to as a “lower side”. Therefore, in each of the conductor layers and insulating layers, a surface facing away from the conductor layer 21 or toward the conductor layer 24 is also referred to as an “upper surface,” and a surface facing away from the conductor layer 24 or toward the conductor layer 21 is also referred to as a “lower surface”.

In each of the insulating layers (31-33), via conductors 4 that penetrate the respective insulating layer are formed. The via conductors 4 are respectively formed in holes 5 that penetrate the respective insulating layer. Each via conductor 4 connects two conductor layers sandwiching the insulating layer (one of the insulating layers (31-33)) that it penetrates. For example, the via conductors 4 penetrating the insulating layer 31 connect the conductor layer 21 and the conductor layer 22. Each via conductor 4 is integrally formed with the conductor layer on its upper side. The via conductors 4 penetrating the insulating layer 31 are integrally formed with the conductor layer 22, the via conductors 4 penetrating the insulating layer 32 are integrally formed with the conductor layer 23, and the via conductors 4 penetrating the insulating layer 33 are integrally formed with the conductor layer 24.

In the description of the wiring substrate of the embodiment, the conductor layer in contact with the lower surface of each insulating layer is also referred to as the first conductor layer, while the conductor layer in contact with the upper surface of each insulating layer is also referred to as the second conductor layer. In the example of FIG. 1, for each of the insulating layers (31-33), the conductor layer integrally formed with the via conductors 4 penetrating the respective insulating layer is also referred to as the second conductor layer, and the conductor layer connected to the second conductor layer via those via conductors 4 is also referred to as the first conductor layer. That is, with respect to the insulating layer 31, the conductor layer 21 can be the first conductor layer relative to the conductor layer 22, and the conductor layer 22 can be the second conductor layer relative to the conductor layer 21. Similarly, with respect to the insulating layer 32, the conductor layer 22 can be the first conductor layer relative to the conductor layer 23, and the conductor layer 23 can be the second conductor layer relative to the conductor layer 22. Further, with respect to the insulating layer 33, the conductor layer 23 can be the first conductor layer relative to the conductor layer 24, and the conductor layer 24 can be the second conductor layer relative to the conductor layer 23.

In this way, the wiring substrate of the embodiment, such as the wiring substrate 1, includes, for example, a first conductor layer such as the conductor layer 21, an insulating layer such as the insulating layer 31 covering the first conductor layer, and a second conductor layer such as the conductor layer 22 formed on a surface of the insulating layer. Further, the wiring substrate of the embodiment includes the via conductors 4 that connect the first conductor layer and the second conductor layer.

The wiring substrate 1 in FIG. 1 further includes a solder resist 61 covering the lower surface of the conductor layer 21 and the lower surface of the insulating layer 31, as well as a solder resist 62 covering the upper surface of the conductor layer 24 and the upper surface of the insulating layer 33. The solder resists (61, 62) are formed of, for example, photosensitive epoxy resin. In the solder resists, openings are formed that each expose a predetermined region of the conductor layer 21 or the conductor layer 24.

The conductor layers (21-24) and the via conductors 4 are each formed of any metal with suitable conductivity. Examples of materials constituting these conductive elements include copper, nickel, gold, titanium, palladium, tungsten, and the like. However, the materials of the conductor layers (21-24) and the via conductors 4 are not limited to these metals.

In FIG. 1, the conductor layers (21-24) and the via conductors 4 are depicted in a simplified manner as being each composed of only one layer, but as illustrated in FIG. 2, they may each have a multilayer structure composed of two or more metal films. In the example of FIG. 2, the conductor layer 21 and the via conductor 4 are composed of a lower layer formed of a metal film (4a) and an upper layer formed of a plating film (4b). The metal film (4a) may be, for example, an electroless plating film or a sputtering film of copper, and the plating film (4b) may be, for example, an electrolytic plating film of copper.

The insulating layers (31-33) are primarily formed of any insulating resin. Examples of the insulating resin used to form the insulating layers (31-33) include epoxy resin, bismaleimide triazine resin (BT resin), phenol resin, fluororesin, liquid crystal polymer (LCP), acrylic resin, fluorinated ethylene (PTFE) resin, polyester (PE) resin, and modified polyimide (MPI) resin. It is preferable that these resins constituting the insulating layers (31-33) are photosensitive resins having properties that react to light, such as photocuring (negative type) resins that cross-link upon receiving light such as ultraviolet light, or photodissolving (positive type) resins that decompose upon receiving light. For example, the resins exemplified above, which primarily constitute the insulating layers (31-33), may themselves be photosensitive, or the insulating layers (31-33) may include a photosensitizer in addition to the exemplified resins. It may be more preferable that the photosensitive resin constituting the insulating layers (31-33) is of the negative type.

On the other hand, it is preferable that the insulating layers (31-33) do not contain inorganic particles made of, for example, silicon oxide or alumina, which are generally used as fillers for adjusting various properties such as mechanical properties. Further, it is preferable that the insulating layers (31-33) do not contain core materials, such as glass fibers, which are generally used for improving mechanical strength. The resins listed above as materials for the insulating layers (31-33) are merely examples of materials capable of forming the insulating layers. The insulating layers can be formed of any material capable of providing insulation to the conductor layers (21-24) and supporting the conductor layers (21-24).

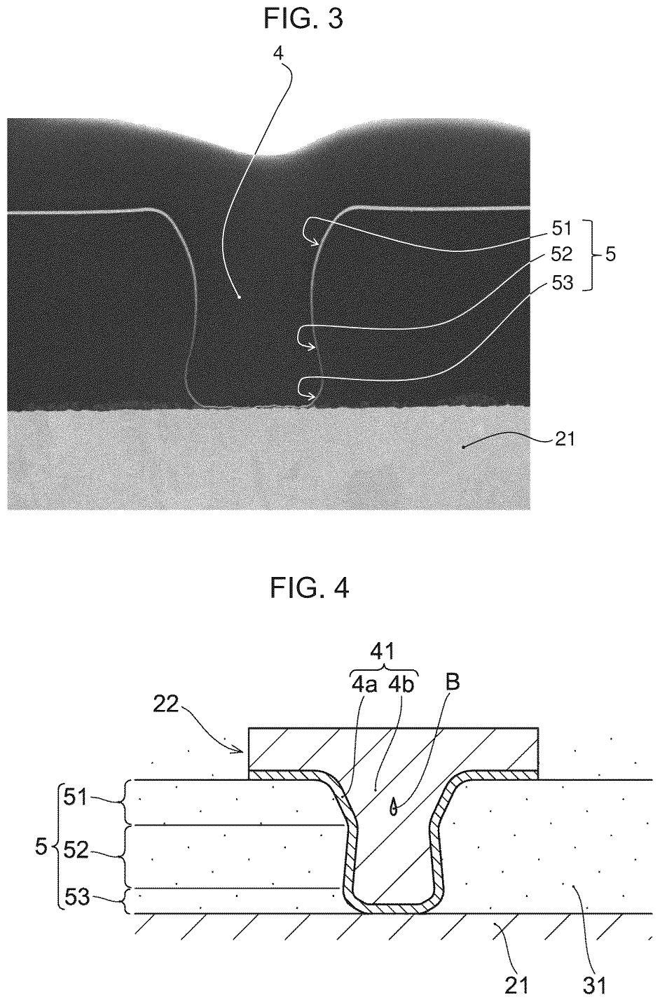

In the wiring substrate of the embodiment, as illustrated in FIG. 2, the hole 5 filled with the via conductor 4 includes a first portion 51, a second portion 52, and a third portion 53. The first portion 51 is a portion that is decreased in width more on the conductor layer 21 side than on the conductor layer 22 side in the example of FIG. 2. The second portion 52 is a portion that is wider in width on the conductor layer 21 side than on the conductor layer 22 side and is located on the conductor layer 21 side of the first portion 51. The third portion 53 is a portion that is decreased in width more on the conductor layer 21 side than on the conductor layer 22 side and is located on the conductor layer 21 side of the second portion 52. In FIG. 2, which illustrates the insulating layer 31 and the conductor layers (21, 22) above and below it, as described above, the conductor layer 21 is the first conductor layer, and the conductor layer 22 is the second conductor layer. In descriptions referencing FIG. 2, as well as in descriptions referencing FIGS. 3 to 5, which similarly illustrate the insulating layer 31 and the conductor layers (21, 22) above and below it, the conductor layer 21 is also referred to as the first conductor layer 21, and the conductor layer 22 is also referred to as the second conductor layer 22.

In the wiring substrate of the embodiment, as illustrated in FIG. 2, the hole 5 filled with the via conductor 4 has, as described above, the first portion 51, the second portion 52, and the third portion 53, each of which decreases or increases in width on the first conductor layer 21 side compared to the second conductor layer 22 side. The first portion 51 and the third portion 53 decrease in width toward the first conductor layer 21, whereas the second portion 52 increases in width toward the first conductor layer 21. The “width” of each of the first portion 51, the second portion 52, and the third portion 53, that is, the “width” of the hole 5, is a maximum distance between any two points on an outer periphery of the hole 5 in any cross-sectional plane orthogonal to the Z direction.

The first portion 51, the second portion 52, and the third portion 53 are formed in series in this order along the Z direction from the second conductor layer 22 side to the first conductor layer 21 side.

Since the hole 5 has the first portion 51, the second portion 52, and the third portion 53 as illustrated in FIG. 2, it is thought that a crack or delamination due to a void or the like is unlikely to occur between the via conductor 4 formed in the hole 5 and the first conductor layer 21. One reason for this is that it is thought that the via conductor 4 is unlikely to contain a void in the third portion 53, which constitutes a portion near a bottom of the hole 5. That is, in the formation of the via conductor 4 by filling the hole 5 with the metal film (4a) and the plating film (4b), the presence of the second portion 52, which increases in width toward the first conductor layer 21 side, is thought to allow a plating solution, such as that used in electrolytic plating, to easily penetrate deep into the hole 5. Therefore, it is thought that the metal film (4a) and the plating film (4b) can be easily formed throughout the entire interior of the hole 5.

In addition, due to the presence of the third portion 53, which decreases in width toward the first conductor layer 21 side, it is thought that a portion like an imaginary portion (IM) indicated with a dashed line in FIG. 2 is unlikely to form at a peripheral edge of the hole 5 near an interface with the first conductor layer 21. For example, when the second portion 52 extends to the first conductor layer 21, a tapered corner portion like the imaginary portion (IM) may be formed in the hole 5 near the interface with the first conductor layer 21. When the hole 5 includes a portion like the imaginary portion (IM), it is difficult for fresh plating solution to flow into such a portion, and therefore, it is thought that a via conductor formed in a hole containing a portion like the imaginary portion (IM) is likely to contain an unfilled portion, such as a void, near its bottom.

In contrast, in the wiring substrate 1 of the embodiment, since the hole 5 includes the third portion 53, a portion like the imaginary portion (IM) illustrated in FIG. 2 is unlikely to form. That is, the via conductor 4 is unlikely to contain an unfilled portion, such as a void, near its bottom. Therefore, in the wiring substrate of the embodiment, due to the above-described effect of at least the second portion 52 and the third portion 53 in the hole 5, a crack or delamination is unlikely to occur between the via conductor 4 and the first conductor layer 21. Therefore, it is thought that a defect such as delamination between the via conductor 4 and the first conductor layer 21 is suppressed.

The hole 5 can have any opening shape, such as circular or elliptical, at both end surfaces and in cross sections orthogonal to the Z direction. When the hole 5 has a circular or elliptical opening shape, the first portion 51 and the third portion 53 may decrease in diameter toward the first conductor layer 21 side, while the second portion 52 may increase in diameter toward the first conductor layer 21 side. Further, in the first portion 51 and the third portion 53, the width of the hole 5 may be smaller on the first conductor layer 21 side than on the second conductor layer 22 side, while in the second portion 52, the width of the hole 5 may be larger on the first conductor layer 21 side than on the second conductor layer 22 side. In other words, in the first portion 51 and the third portion 53, the width of the hole 5 may gradually decrease as it approaches the first conductor layer 21, while in the second portion 52, the width of the hole 5 may gradually increase as it approaches the first conductor layer 21. In this case, in the first portion 51 and the third portion 53, the width of the hole 5 may decrease continuously or stepwise as it approaches the first conductor layer 21, while in the second portion 52, the width of the hole 5 may increase continuously or stepwise as it approaches the first conductor layer 21.

Further, a width (W1) at an opening end (upper end) of the first portion 51 on the second conductor layer 22 side may be larger than a width (W2) at an opening end (lower end) on the first conductor layer 21 side, and a width (W3) at an upper end of the second portion 52 (which is the same as the width (W2) in FIG. 2) may be smaller than a width (W4) at a lower end. Further, a width (W5) at an upper end of the third portion 53 (which is the same as the width (W4) in FIG. 2) may be larger than a width (W6) at a lower end.

Further, in the wiring substrate 1 of the embodiment, a wall surface (5a) of the hole 5 may be inclined inward toward the first conductor layer 21 in the first portion 51. Further, the wall surface (5a) of the hole 5 may be inclined outward toward the first conductor layer 21 in the second portion 52. Further, the wall surface (5a) of the hole 5 may be inclined inward toward the first conductor layer 21 in the third portion 53. In other words, the first portion 51 and the third portion 53 can have a forward taper toward the first conductor layer 21, while the second portion 52 can have a reverse taper toward the first conductor layer 21.

The hole 5 having a shape that includes the first portion 51, the second portion 52, and the third portion 53, an example of which is illustrated in FIG. 2, is formed, as an example, by irradiating each insulating layer with light, such as ultraviolet light, using a predetermined exposure pattern and removing irradiated portions or non-irradiated portions by development. In other words, the via conductor 4 may be a so-called “photo via”. In this way, to facilitate easy formation of the hole 5 by photolithography involving exposure and development, each insulating layer, such as the insulating layer 31, in the wiring substrate of the embodiment is preferably formed of a photosensitive resin, as described above. For the same reason, each insulating layer, such as the insulating layer 31, is preferably formed of a resin that does not contain inorganic particles made of silicon oxide or alumina or the like, commonly referred to as “inorganic fillers.” Further, for the same reason, each insulating layer, such as the insulating layer 31, is preferably formed of a resin that does not contain a core material made of glass fibers or the like.

In the formation of the hole 5 by photolithography, it may be possible to form holes with minute widths more easily than, for example, drilling by laser irradiation. Therefore, in the wiring substrate 1, the hole 5 can have a relatively minute opening width. Further, in the wiring substrate of the embodiment, as described above, since a crack or delamination is unlikely to occur between the via conductor 4 and the first conductor layer 21, a defect such as an open failure or an increase in electrical resistance is unlikely to occur between the via conductor 4 and the first conductor layer 21, even when the via conductor 4 has a small width. Therefore, it is thought that the wiring substrate of the embodiment is suitable as a wiring substrate that includes minute via conductors. For example, in the wiring substrate 1, an opening width (W) of the hole 5 at an interface between the insulating layer 31 and the second conductor layer 22 (which is the same as the width (W1) at the upper end of the first portion 51 in FIG. 2) may be 3 μm or more and 10 μm or less. When the hole 5 has a minute opening width in such a range, the wiring substrate 1 may be able to include fine wiring patterns at high density.

In the hole 5 of the wiring substrate 1 illustrated in FIG. 2, in the thickness direction (Z direction) of the wiring substrate 1, a length (L3) of the third portion 53 is shorter than a length (L1) of the first portion 51 and also shorter than a length (L2) of the second portion 52. Therefore, it is thought that a contact area between the via conductor 4 and the first conductor layer 21 does not become excessively small and an appropriate contact area is maintained. As an example, relative to a thickness (T31) of the insulating layer 31, the length (L1) of the first portion 51 is about 30%, the length (L2) of the second portion 52 is about 60%, and the length (L3) of the third portion 53 is about 10%.

The thickness (T31) of the insulating layer 31 is, for example, 3 μm or more and 15 μm or less. An aspect ratio of the via conductor 4 formed in the insulating layer 31 with such a thickness is, for example, 1.0 or more and 3.0 or less. The aspect ratio of the via conductor 4 is a ratio expressed as (the width (W6) of the hole 5 at the lower end of the third portion 53)/(a distance between the first conductor layer 21 and the second conductor layer 22).

Further, in the hole 5 of the wiring substrate 1 illustrated in FIG. 2, an inclination (θ1) of the wall surface (5a) of the hole 5 with respect to the thickness direction (Z direction) of the wiring substrate 1 in the first portion 51 is greater than an inclination (θ2) of the wall surface (5a) of the hole 5 with respect to the Z direction in the second portion 52. Therefore, during the formation of the via conductor 4 by plating, it is thought that the plating solution can easily penetrate into the hole 5, allowing the via conductor 4 to be formed quickly. The inclination (θ1) is determined by an arctangent of an absolute value of (the length (L1) of the first portion 51)/((the width (W1) at the upper end of the first portion 51−the width (W2) at the lower end)/2). The inclination (θ2) is similarly determined for the second portion 52.

Further, in the hole 5 of the wiring substrate 1 illustrated in FIG. 2, the second portion 52 is connected to the first portion 51, and the third portion 53 is connected to the second portion 52. Further, the first portion 51 is in contact with the second conductor layer 22, and the third portion 53 is in contact with the first conductor layer 21. That is, the hole 5 in the example of FIG. 2 consists of the first portion 51, the second portion 52, and the third portion 53, that is, it is composed of only the first portion 51, the second portion 52, and the third portion 53. Therefore, there is an advantage that it is easy to control so that no void is formed in the third portion 53.

FIG. 3 illustrates a captured image of a cross section of a via conductor 4 in an example of the wiring substrate of the embodiment. As described with reference to FIG. 2, in FIG. 3, the hole 5 filled with the via conductor 4 includes a first portion 51 that decreases in width toward the first conductor layer 21 side, a second portion 52 that is located on the first conductor layer 21 side of the first portion 51 and increases in width toward the first conductor layer 21 side, and a third portion 53 that is located on the first conductor layer 21 side of the second portion 52 and decreases in width toward the first conductor layer 21 side. In this way, the wiring substrate of the embodiment indeed includes the via conductor 4 formed in a hole 5 having the first portion 51, the second portion 52, and the third portion 53.

### First Modified Example

FIG. 4 illustrates a via conductor 41 penetrating the insulating layer 31 and their surrounding portions in a first modified example of the wiring substrate of the embodiment. In the modified example of FIG. 4, the via conductor 41 is formed in a hole 5 penetrating the insulating layer 31. The via conductor 41 is formed by a metal film (4a) and a plating film (4b) filling the hole 5, and connects the first conductor layer 21 and the second conductor layer 22. The hole 5, similar to the example illustrated in FIG. 2, includes a first portion 51, a second portion 52, and a third portion 53. In the example of FIG. 4, the via conductor 41 does not contain any voids in a portion of the plating film (4b) that fills the third portion 53, but contains a void (B) in a portion that fills the first portion 51. In the first modified example illustrated in FIG. 4, where the void (B) is contained in the first portion 51 rather than the third portion 53, it is thought that delamination between the via conductor 41 and the first conductor layer 21 is unlikely to occur compared to the case where voids exist at a bottom part of a via conductor in a conventional wiring substrate. In the first modified example of FIG. 4, the void (B) may be contained in the second portion 52 instead of the first portion 51, or may be contained in the second portion 52 in addition to the first portion 51. Even in such cases, since the third portion 53 does not contain any voids, it is thought that delamination between the via conductor 41 and the first conductor layer 21 is unlikely to occur.

### Second Modified Example

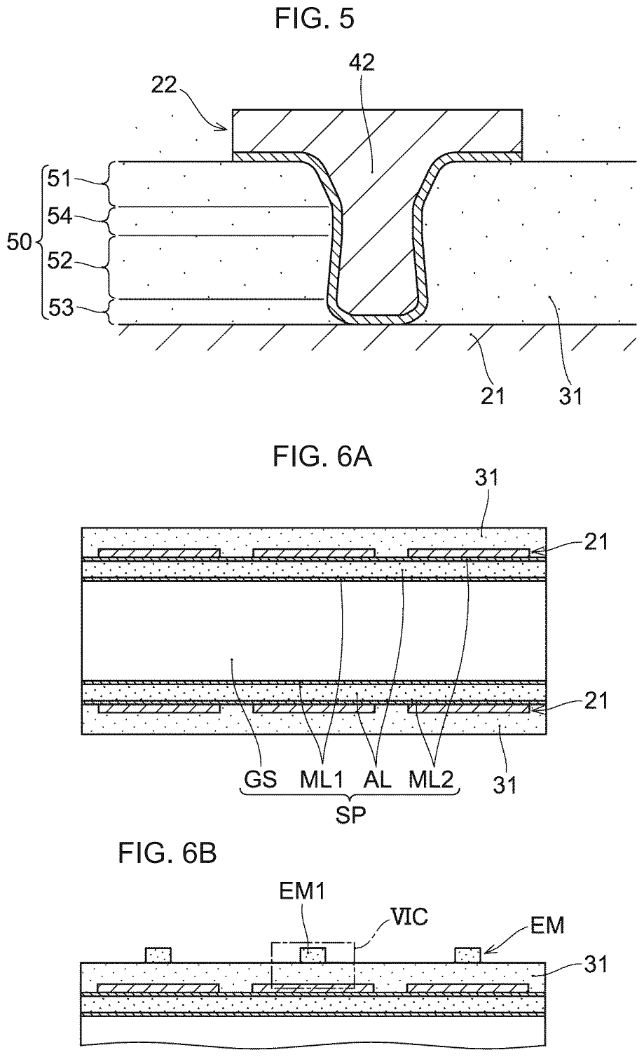

FIG. 5 illustrates a via conductor 42 penetrating the insulating layer 31 and their surrounding portions in a second modified example of the wiring substrate of the embodiment. The via conductor 42 is formed in a hole 50 penetrating the insulating layer 31 and connects the first conductor layer 21 and the second conductor layer 22. The hole 50 included in the modified example of FIG. 5 also has a first portion 51 that decreases in width toward the first conductor layer 21 side, a second portion 52 that is located on the first conductor layer 21 side of the first portion 51 and increases in width toward the first conductor layer 21 side, and a third portion 53 that is located on the first conductor layer 21 side of the second portion 52 and decreases in width toward the first conductor layer 21 side.

Further, the hole 50 in the example of FIG. 5 also further has a fourth portion 54 that substantially does not change in width from the second conductor layer 22 side to the first conductor layer 21 side. In other words, in the fourth portion 54, the width of the hole 50 is substantially constant from its upper end to its lower end. The hole 50 in the example of FIG. 5 has the fourth portion 54 between the first portion 51 and the second portion 52. However, in the wiring substrate of the embodiment, when a hole for a via conductor, such as the hole 50, has a parallel portion that does not change in width, it is also possible that the parallel portion is located between the second portion 52 and the third portion 53. As in the example of FIG. 5, in the wiring substrate of the embodiment, the hole filled with the via conductor may include a parallel portion, such as the fourth portion 54, in addition to the first portion 51, the second portion 52, and the third portion 53. Further, in the wiring substrate of the embodiment, the hole filled with the via conductor may include, in addition to the first to third portions (51-53), a portion that increases or decreases in diameter toward the first conductor layer 21 side.

### Method for Manufacturing Wiring Substrate

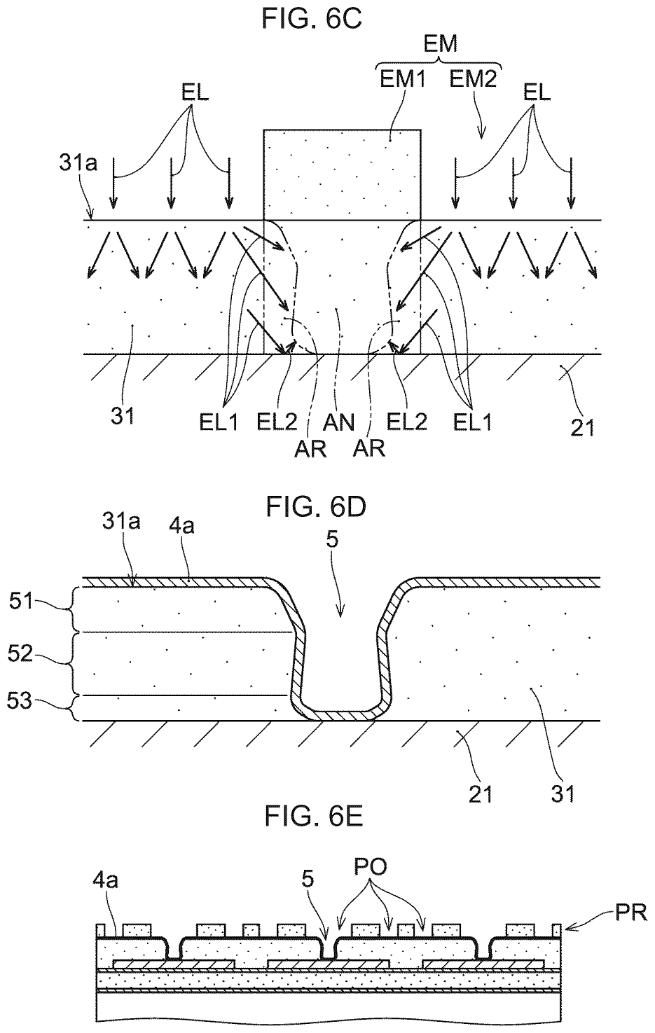

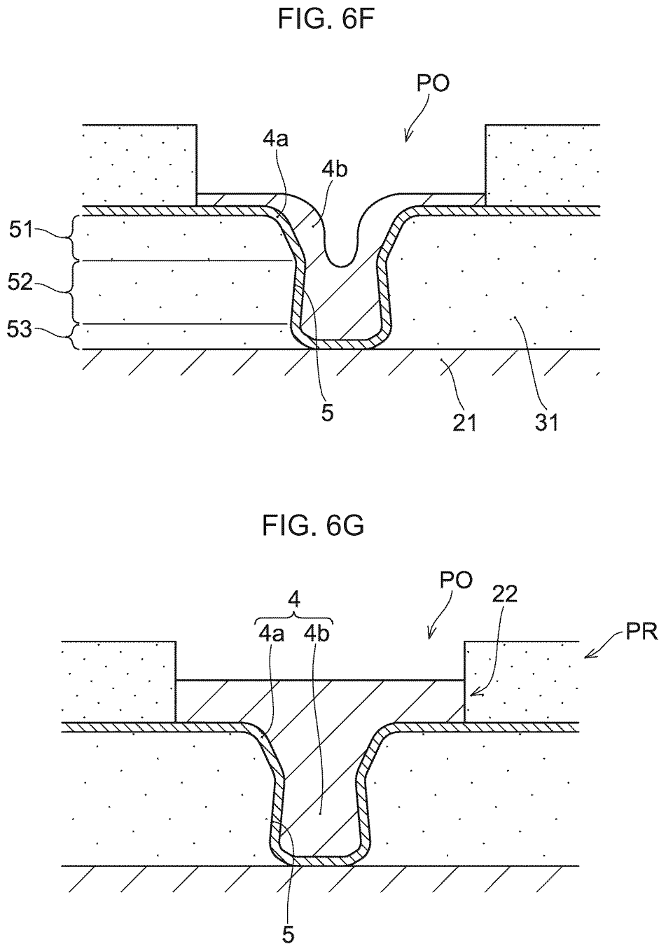

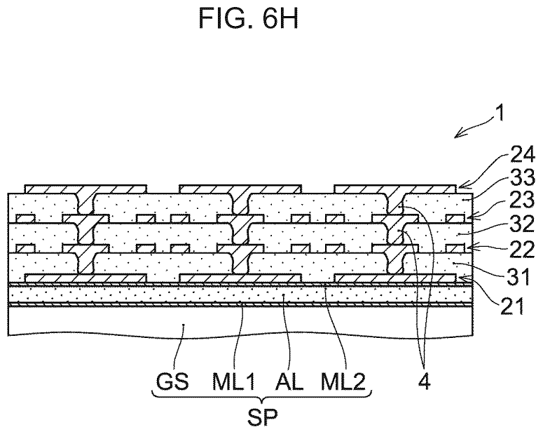

With reference to FIGS. 6A to 6H, an example of a method for manufacturing the wiring substrate of the embodiment is described, using the wiring substrate 1 illustrated in FIG. 1 as an example.

As illustrated in FIG. 6A, a support substrate (SP) is prepared, which includes a core layer (GS) and metal film layers (ML1, ML2) laminated on each of two surfaces of the core layer (GS). The core layer (GS) is constituted by, for example, a glass material or a glass epoxy material. The metal film layers (ML1, ML2) are each, for example, a single-layer or multi-layer metal film formed by electroless plating or sputtering using materials such as copper and titanium or the like. The metal film layer (ML1) and the metal film layer (ML2) are bonded together by, for example, an adhesive layer (AL) constituted by an adhesive whose adhesiveness changes upon exposure to light.

In the following description, a side closer to the core layer (GS) of the support substrate (SP) is also referred to as “lower” or “lower side”, and a side farther from the core layer (GS) is also referred to as “upper” or “upper side”. Therefore, of each of the elements constituting the wiring structure, a surface facing the support substrate (SP) is also referred to as a “lower surface”, and a surface facing the opposite side with respect to the support substrate (SP) is also referred to as an “upper surface”.

The conductor layer 21 is formed on the metal film layer (ML2) on both surfaces of the prepared support substrate (SP). In the formation of the conductor layer 21, for example, a plating resist (not illustrated) having predetermined openings is formed on the metal film layer (ML2). By electrolytic plating using the metal film layer (ML2) as a power feeding layer, a plating film is deposited in the openings of the plating resist. After that, the plating resist is removed. The conductor layer 21, including conductor patterns formed of the plating film deposited in the openings of the plating resist, is formed.

After the formation of the conductor layer 21, the insulating layer 31 covering the conductor layer 21 is formed. The insulating layer 31 is preferably formed of a photosensitive resin. Examples of the photosensitive resin include epoxy resin, BT resin, phenol resin, and the like, with a photosensitizer added. In the formation of the insulating layer 31, for example, a resin film made of a resin that constitutes the insulating layer 31, such as epoxy resin, is laminated on the conductor layer 21 and the metal film layer (ML2), and is then preliminarily cured, for example by heating, to an intermediate reaction state such as a B-stage state. In one example, the photosensitive resin constituting the insulating layer 31 is of the negative type. In the following, the method of forming the hole 5 (see FIG. 6D) in the insulating layer 31 is described, taking the case where the photosensitive resin constituting the insulating layer 31 is of the negative type as an example.

As illustrated in FIG. 6B, an exposure mask (EM) having a shielding part (EM1) at a formation position of a via conductor 4 (see FIG. 6G) is provided on the insulating layer 31, for example, by laminating a dry film resist, followed by exposure and development. In FIG. 6B, as well as in FIGS. 6E and 6H to be referenced later, only one surface side of the support substrate (SP) is illustrated, and illustration of a state on the other side is omitted. However, on the surface of the support substrate (SP) on the side where illustration is omitted, insulating layers and conductor layers may be formed in the same manner as on the illustrated side, or it is also possible that such conductor layers and insulating layers are not formed.

FIG. 6C illustrates an enlarged view of a portion (VIC) of FIG. 6B. As illustrated in FIG. 6C, for example, exposure light (EL), such as ultraviolet light, is irradiated onto the insulating layer 31 through the exposure mask (EM). A wavelength of the exposure light (EL) is selected according to photosensitive properties of the photosensitive resin constituting the insulating layer 31. The exposure light (EL) irradiates a portion of an upper surface (31a) of the insulating layer 31 that is exposed through an opening (EM2) of the exposure mask (EM). By adjusting a diffusion or irradiation angle of the exposure light (EL), exposure light (EL1), which is a portion of the exposure light (EL1) that has penetrated into the insulating layer 31, propagates in the insulating layer 31 so as to spread even to a portion directly beneath the shielding part (EM1) of the exposure mask (EM). Therefore, in the insulating layer 31 directly beneath the shielding part (EM1), a portion near the opening (EM2) is exposed by the exposure light (EL1). In the insulating layer 31 formed of a negative-type photosensitive resin, the exposed portions are cross-linked. Therefore, even in a portion directly beneath the shielding part (EM1), in a region (AR) exposed to the exposure light (EL1), a cross-linking reaction proceeds similarly to the portion near directly beneath the opening (EM2).

Here, it is thought that the exposure light (EL) propagating in the insulating layer 31 gradually weakens in intensity in a portion near the conductor layer 21, away from the upper surface (31a) of the insulating layer 31. Therefore, the region (AR) that is exposed in the portion directly beneath the shielding part (EM1) gradually becomes smaller as it approaches the conductor layer 21 in a portion that is separated to some extent from the upper surface (31a). Therefore, in a portion of the insulating layer 31 directly beneath the shielding part (EM1) that is separated to some extent from the upper surface (31a), a region (AN) that does not exhibit cross-linking reaction gradually becomes larger as it approaches the conductor layer 21.

On the other hand, in the insulating layer 31, immediately adjacent to the conductor layer 21, a small portion of the portion directly beneath the shielding part (EM1) near the portion directly beneath the opening (EM2) is exposed by reflected light (EL2) of the exposure light (EL1) reflected from the surface of the conductor layer 21. Therefore, the exposed region (AR) directly beneath the shielding part (EM1) expands in the portion immediately adjacent to the conductor layer 21. That is, in the portion of the insulating layer 31 directly beneath the shielding part (EM1) and immediately adjacent to the conductor layer 21, the region (AN) that does not exhibit cross-linking reaction decreases in width. As a result, as illustrated in FIG. 6C, the region (AN) that does exhibit cross-linking reaction decreases in width as it approaches the conductor layer 21 in a certain range near the upper surface (31a) of the insulating layer 31, and, on the conductor layer 21 side, it increases in width as it approaches the conductor layer 21, and then decreases in width as it approaches the conductor layer 21 in a small region immediately adjacent to the conductor layer 21. This region (AN) that does not exhibit cross-linking reaction is removed in a later process.

After the irradiation of the exposure light (EL) onto the insulating layer 31, the exposure mask (EM) is removed using an appropriate stripping agent. By performing development after the removal of the exposure mask (EM), the region (AN) in the insulating layer 31 that does not exhibit cross-linking reaction in the above-described exposure process is removed.

Through the removal of the region (AN) that does not exhibit cross-linking reaction, the hole 5 is formed in the insulating layer 31, as illustrated in FIG. 6D. As described above, since the region (AN) that does not exhibit cross-linking reaction has three portions that decrease or increase in width as it approaches the conductor layer 21, the hole 5 with a shape illustrated in FIG. 6D is formed. In other words, the hole 5 is formed having the first portion 51 that decreases in width toward the conductor layer 21 side, the second portion 52 that increases in width toward the conductor layer 21 side, and the third portion 53 that decreases in width toward the conductor layer 21 side. The second portion 52 is located on the conductor layer 21 side of the first portion 51, and the third portion 53 is located on the conductor layer 21 side of the second portion 52. In the hole 5 in the example of FIG. 6D, the second portion 52 is connected to the first portion 51, and the third portion 53 is connected to the second portion 52. The hole 5 in the example of FIG. 6D consists of only the first portion 51, the second portion 52, and the third portion 53.

As described above, by appropriately selecting and adjusting the irradiation conditions, such as the diffusion or irradiation angle and intensity of the exposure light (EL) (see FIG. 6C), the hole 5 including the first to third portions (51-53) as illustrated in FIG. 6D can be formed. Further, the hole 50 having the fourth portion 54, as illustrated in FIG. 5 referenced above, can also be formed by adjusting the irradiation conditions of the exposure light (EL).

After the formation of the hole 5, for example, the metal film (4a) made of copper is formed on the upper surface (31a) of the insulating layer 31 and in the hole 5 by electroless plating or sputtering.

As illustrated in FIG. 6E, a plating resist (PR) is provided on the metal film (4a), for example, by laminating a dry film resist. Openings (PO) are formed in the plating resist (PR), for example, by photolithography. The openings (PO) are provided in regions where conductor patterns of the conductor layer 22 (see FIG. 6H) are to be formed. An opening (PO) is also provided above each hole 5.

As illustrated in FIG. 6F, the plating film (4b) is deposited in the opening (PO) by electrolytic plating, for example, using the metal film (4a) as a power feeding layer. The plating film (4b) is also deposited in the hole 5 exposed in the opening (PO), and the hole 5 is gradually filled with the plating film (4b). In the hole 5 having the first to third portions (51-53), as described above, the plating solution can easily penetrate to the bottom of the hole 5, and since there is no portion near the bottom where the plating solution has difficulty circulating, the hole 5 is easily filled with the plating film (4b) throughout the entire third portion 53. In other words, an unfilled portion such as a void is unlikely to form near the interface with the conductor layer 21 at the bottom of the hole 5.

The plating film (4b) fills the entire third portion 53, fills the entire second portion 52, and further fills the first portion 51. In the manufacturing of the wiring substrate of the embodiment, since the second portion 52 that increases in width toward the conductor layer 21 side is present, it may take a relatively longer time to fill the third portion 53 and the second portion 52. In that case, after the second portion 52 is filled, before the first portion 51 is completely filled, a vicinity of the upper end of the first portion 51 may be blocked by the plating film (4b) that deposits on an inner wall around the hole 5. Alternatively, by forming the hole 5 with the desired shape through adjustment of the irradiation conditions of the exposure light (EL) (see FIG. 6C) as described above, or by adjusting plating conditions, the vicinity of the upper end of the first portion 51 may be blocked by the plating film (4b) deposited on the inner walls surrounding the hole 5 before the first portion 51 or the second portion 52 is completely filled. In this case, a void (B) as illustrated in FIG. 4 referenced above is formed in the first portion 51 and/or the second portion 52. Even in this case, since the void (B) is unlikely to form in the third portion 53 (particularly near the interface with the conductor layer 21), it is thought that in the wiring substrate of the embodiment, a crack or delamination between the via conductor 4 formed in the hole 5 (see FIG. 6G) and the conductor layer 21 is suppressed.

As illustrated in FIG. 6G, from the state illustrated in FIG. 6F, through continued deposition of the plating film (4b) by continuing the electrolytic plating, the entire hole 5 is filled with the plating film (4b), and further, the opening (PO) of the plating resist (PR) is filled to a predetermined depth. As a result, the via conductors 4 are formed within the holes 5, and the conductor pads of the conductor layer 22 (see FIG. 6H) are formed in the openings (PO).

After the formation of the plating film (4b), and the formation of the via conductors 4 by the formation of the plating film (4b), the plating resist (PR) is removed using an appropriate stripping solution. Further, a portion of the metal film (4a) exposed by the removal of the plating resist (PR) is removed, for example, by etching. As a result, the conductor layer 22, formed of the conductor patterns formed in the openings (PO) of the plating resist (PR), is formed.

As illustrated in FIG. 6H, the insulating layer 32, the conductor layer 23, and the via conductors 4 penetrating the insulating layer 32 are further formed using methods similar to those described above for forming the insulating layer 31, the conductor layer 22, and the via conductors 4. Further, the insulating layer 33, the conductor layer 24, and the via conductors 4 penetrating the insulating layer 33 are formed using methods similar to those for forming the insulating layer 31, the conductor layer 22, and the via conductors 4 penetrating the insulating layer 31.

The solder resist 62 (see FIG. 1) is formed on the conductor layer 24 and the insulating layer 33. The solder resist 62 is formed, for example, using a photosensitive polyimide resin or epoxy resin, using any method such as spraying, laminating, or coating. It is also possible that the solder resist 62 is formed not immediately after the formation of the conductor layer 24 but after the removal of the metal film layer (ML2) of the support substrate (SP), which will be described below.

The core layer (GS) of the support substrate (SP) is removed. The lower surface of the metal film layer (ML2) of the support substrate (SP) is exposed. The core layer (GS) is removed, for example, by peeling the metal film layer (ML2) from the adhesive layer (AL) after the adhesive layer (AL) has been softened by laser irradiation. Then, the metal film layer (ML2) is removed by etching. The lower surface of the conductor layer 21 and the lower surface of the insulating layer 31 are exposed. The solder resist 61 (see FIG. 1) covering the exposed conductor layer 21 and insulating layer 31 is formed using a method similar to that for forming the solder resist 62.

As illustrated in FIG. 1, the openings exposing the conductor layer 21 or the conductor layer 24 are formed in the solder resists (61, 62). The openings in the solder resists (61, 62) are formed, for example, by photolithography including exposure and development processes, or by laser irradiation, or the like. For example, through the above processes, the wiring substrate 1 of the embodiment illustrated in FIG. 1 can be manufactured.

The wiring substrate of the embodiment is not limited to those having the structures illustrated in the drawings and those having the structures, shapes, and materials exemplified herein. As described above, the wiring substrate of the embodiment can have any laminated structure. In any insulating layer of the wiring substrate of the embodiment, a hole that is filled with a via conductor and has three portions such as the first to third portions (51-53) may be formed. In the wiring substrate of the embodiment, in at least one insulating layer, a via conductor is formed filling a hole that has three portions such as the first to third portions (51-53). The wiring substrate of the embodiment does not need to be a so-called coreless substrate like the wiring substrate 1 of FIG. 1, and may include a core substrate and build-up layers formed on both sides thereof.

Japanese Patent Application Laid-Open Publication No. 2020-17639 describes a wiring substrate that includes a via hole conductor filled in a via hole penetrating an insulating layer. A via bottom portion of the via hole conductor is formed of crystal particles smaller than those forming the other portions to prevent cracks or delamination between the via hole conductor and a via land.

In the wiring substrate described in Japanese Patent Application Laid-Open Publication No. 2020-17639, precise control of conditions is required in electrolytic plating during formation of the via hole conductor in order to form the via bottom portion with small crystal particles, and therefore, manufacturing of the wiring substrate may become complicated. Further, it is thought that an unnecessary interface is generated between the via bottom portion and the other portions, these portions being formed with crystal particles of different sizes from each other. However, when the via bottom portion is not formed with small crystal particles, cracks or delamination may occur between the via hole conductor and the via land.

A wiring substrate according to an embodiment of the present invention includes: a first conductor layer; an insulating layer that covers the first conductor layer; a second conductor layer that is formed on a surface of the insulating layer; and a via conductor that is formed in a hole penetrating the insulating layer and connects the first conductor layer and the second conductor layer. The hole includes: a first portion that decreases in width on the first conductor layer side; a second portion that is located on the first conductor layer side of the first portion and increases in width on the first conductor layer side; and a third portion that is located on the first conductor layer side of the second portion and decreases in width on the first conductor layer side.

According to an embodiment of the present invention, in an easy-to-manufacture wiring substrate, it may be possible to suppress delamination between a via conductor and a conductor layer.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a first conductor layer;
an insulating layer covering the first conductor layer;
a second conductor layer formed on a surface of the insulating layer; and
a via conductor formed in a hole penetrating through the insulating layer such that the via conductor is connecting the first conductor layer and the second conductor layer,
wherein the insulating layer is formed such that the hole includes a first portion decreasing in width on the first conductor layer side, a second portion formed on the first conductor layer side of the first portion and increasing in width on the first conductor layer side, and a third portion formed on the first conductor layer side of the second portion and decreasing in width on the first conductor layer side.

2. The wiring substrate according to claim 1, wherein the insulating layer comprises a photosensitive resin.

3. The wiring substrate according to claim 1, wherein the insulating layer comprises a resin that does not contain inorganic particles.

4. The wiring substrate according to claim 1, wherein the via conductor includes a plating film comprising a portion filling the first portion of the hole, a portion filling the second portion of the hole and a portion filling the third portion of the hole such that the portion filling the third portion does not contain voids and that the portion filling the first portion or the portion filling the second portion contains voids.

5. The wiring substrate according to claim 1, wherein the insulating layer is formed such that the third portion of the hole is shorter than the first portion of the hole and shorter than the second portion of the hole in a thickness direction of the wiring substrate.

6. The wiring substrate according to claim 1, wherein the insulating layer is formed such that an inclination of a wall surface of the hole with respect to a thickness direction of the wiring substrate in the first portion of the hole is greater than an inclination of a wall surface of the hole with respect to the thickness direction in the second portion of the hole.

7. The wiring substrate according to claim 1, wherein the insulating layer is formed such that an opening width of the hole at an interface between the insulating layer and the second conductor layer is in a range of 3 μm to 10 μm.

8. The wiring substrate according to claim 1, wherein the insulating layer is formed such that the second portion of the hole is connected to the first portion of the hole and that the third portion of the hole is connected to the second portion of the hole.

9. The wiring substrate according to claim 8, wherein the insulating layer is formed such that the hole is consisting of the first portion, the second portion, and the third portion.

10. The wiring substrate according to claim 2, wherein the photosensitive resin of the insulating layer does not contain inorganic particles.

11. The wiring substrate according to claim 2, wherein the via conductor includes a plating film comprising a portion filling the first portion of the hole, a portion filling the second portion of the hole and a portion filling the third portion of the hole such that the portion filling the third portion does not contain voids and that the portion filling the first portion or the portion filling the second portion contains voids.

12. The wiring substrate according to claim 2, wherein the insulating layer is formed such that the third portion of the hole is shorter than the first portion of the hole and shorter than the second portion of the hole in a thickness direction of the wiring substrate.

13. The wiring substrate according to claim 2, wherein the insulating layer is formed such that an inclination of a wall surface of the hole with respect to a thickness direction of the wiring substrate in the first portion of the hole is greater than an inclination of a wall surface of the hole with respect to the thickness direction in the second portion of the hole.

14. The wiring substrate according to claim 2, wherein the insulating layer is formed such that an opening width of the hole at an interface between the insulating layer and the second conductor layer is in a range of 3 μm to 10 μm.

15. The wiring substrate according to claim 2, wherein the insulating layer is formed such that the second portion of the hole is connected to the first portion of the hole and that the third portion of the hole is connected to the second portion of the hole.

16. The wiring substrate according to claim 15, wherein the insulating layer is formed such that the hole is consisting of the first portion, the second portion, and the third portion.

17. The wiring substrate according to claim 3, wherein the via conductor includes a plating film comprising a portion filling the first portion of the hole, a portion filling the second portion of the hole and a portion filling the third portion of the hole such that the portion filling the third portion does not contain voids and that the portion filling the first portion or the portion filling the second portion contains voids.

18. The wiring substrate according to claim 3, wherein the insulating layer is formed such that the third portion of the hole is shorter than the first portion of the hole and shorter than the second portion of the hole in a thickness direction of the wiring substrate.

19. The wiring substrate according to claim 3, wherein the insulating layer is formed such that an inclination of a wall surface of the hole with respect to a thickness direction of the wiring substrate in the first portion of the hole is greater than an inclination of a wall surface of the hole with respect to the thickness direction in the second portion of the hole.

20. The wiring substrate according to claim 3, wherein the insulating layer is formed such that an opening width of the hole at an interface between the insulating layer and the second conductor layer is in a range of 3 μm to 10 μm.
